(19) United States
(12) Patent Application Publication
(10) Pub. No.: US 2016/0087602 A1
(43) Pub. Date: Mar. 24, 2016

(54) ADAPTIVE FEEDBACK FOR POWER DISTRIBUTION NETWORK IMPEDANCE BARRIER SUPPRESSION

(71) Applicant: Western Digital Technologies, Inc., Irvine, CA (US)

(72) Inventor: DONALD E. ADAMS, PLEASANTON, CA (US)

(21) Appl. No.: 14/495,868

(22) Filed: Sep. 24, 2014

(51) Int. Cl. H03H 11/12; G05F 3/04

(52) U.S. Cl. CPC H03H 11/12; G05F 3/04

(57) ABSTRACT

An adaptive feedback circuit may include: a filter having a first terminal coupled to a first power supply line and a second terminal coupled to a second power supply line, the filter configured to output a high-frequency signal that is transmitted between the first and second power supply lines; an amplifier configured to receive the high-frequency signal output from the filter and generate an amplified high-frequency signal at an output of the amplifier; and a capacitor having a first terminal coupled to the first power supply line and a second terminal coupled to the output of the amplifier. The capacitor is configured to receive the amplified high-frequency signal, and the amplified high-frequency signal generated by the amplifier controls a voltage applied between the first terminal and the second terminal of the capacitor.

### BACKGROUND

1. Technical Field

Apparatuses and methods consistent with the present inventive concept relate to power distribution networks, and more particularly to reducing noise due to an impedance barrier between the power distribution network and a semiconductor integrated circuit (IC).

2. Related Art

An impedance barrier exists between any switching load on an IC such as CMOS logic on a System-on-Chip (SoC) die and the Power Distribution Network (PDN) for the SoC that includes a Voltage Regulator Module (VRM). The impedance barrier is a result of semiconductor package inductance that forms a parasitic parallel resonant circuit with the on-die capacitance of the IC. When the spectral content of the switching current for the switching load is near the resonant frequency of the parallel resonant circuit, excessive switching noise will be generated that can affect operation of the CMOS logic or other circuits sharing the same PDN.

This problem is conventionally addressed by reducing the inductance, increasing the capacitance, or adding damping resistance to the resonant circuit. Another conventional approach adds a canceling current to reduce the total switching current. These methods, however, add significant cost to a product.

### BRIEF DESCRIPTION OF THE DRAWINGS

Aspects and features of the present inventive concept will be more apparent by describing example embodiments with reference to the accompanying drawings, in which:

FIG. 1 is a schematic diagram illustrating a PDN and a parasitic resonant circuit formed by an IC;

FIG. 2 is a graph illustrating an impedance barrier between the PDN and the IC;

FIG. 3 is a schematic diagram illustrating a PDN and an adaptive feedback circuit according to various embodiments;

FIG. 4 is a graph illustrating an impedance barrier between the PDN and the IC according to various embodiments;

FIG. 5 is a schematic diagram illustrating an implementation of an adaptive feedback circuit according to various embodiments;

FIG. 6 is a block diagram illustrating an integrated circuit having an adaptive feedback circuit according to various embodiments;

FIG. 7 is a block diagram illustrating an SoC having an adaptive feedback circuit according to various embodiments; and

FIG. 8 is a flow chart illustrating a method of reducing noise in a circuit according to various embodiments.

### DETAILED DESCRIPTION

While certain embodiments are described, these embodiments are presented by way of example only, and are not intended to limit the scope of protection. The methods and systems described herein may be embodied in a variety of other forms. Furthermore, various omissions, substitutions, and changes in the form of the example methods and systems described herein may be made without departing from the scope of protection.

### Overview

The parasitic capacitance on a semiconductor IC and its corresponding impedance varies with workload. As more transistors, for example in logic circuits and/or other circuits in which transistors are switched on and off, are inactive (i.e., not switching), the capacitance and available charge to supply active (i.e., switching) transistors in the circuits increases. The parasitic capacitance of the IC is the capacitance of transistor gates in the circuits that are not switching. At the same time, the total resistance and inductance for the inactive transistors in the circuits decreases. The resulting parallel resonance between semiconductor package inductance and IC parasitic capacitance will vary causing the impedance barrier between the PDN and the IC to vary. A semiconductor package pin inductance of 200 pico-henries may create the impedance barrier between the PDN and the IC.

Some embodiments related to the present inventive concept may suppress noise resulting from the impedance barrier by adding an adaptive feedback loop to control a voltage across a capacitance that may serve as a decoupling capacitance. As a result, less capacitance may be needed to achieve an acceptable PDN impedance target to suppress noise.

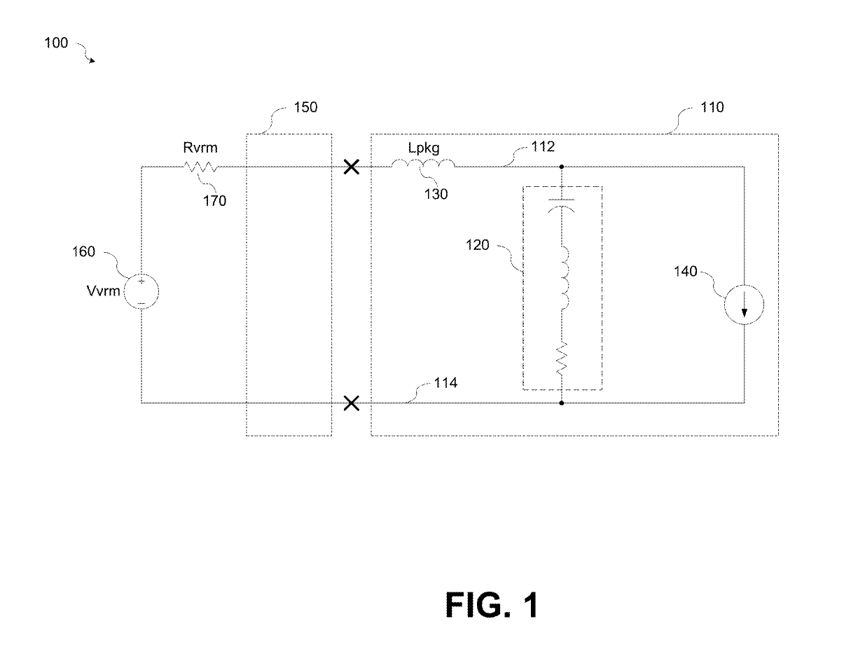

FIG. 1 is a schematic diagram 100 illustrating a PDN and a parasitic resonant circuit formed by an IC. Referring to FIG. 1, a voltage source 160, for example, but not limited to, a voltage regulator module, may supply a switching current 140 through a source resistance 170 and a power distribution network 150 to a first power supply line 112 and a second power supply line 114 that provide power to switching circuitry 110, for example, but not limited to, CMOS logic circuits, of an IC. A parasitic capacitance 120 of the IC in combination with a semiconductor package pin inductance 130 on one or both of the first power supply line 112 and second power supply line 114 may form a parallel resonant circuit at or near the switching frequency, or spectral components thereof, of the switching current 140 that creates an impedance barrier between the PDN and the IC.

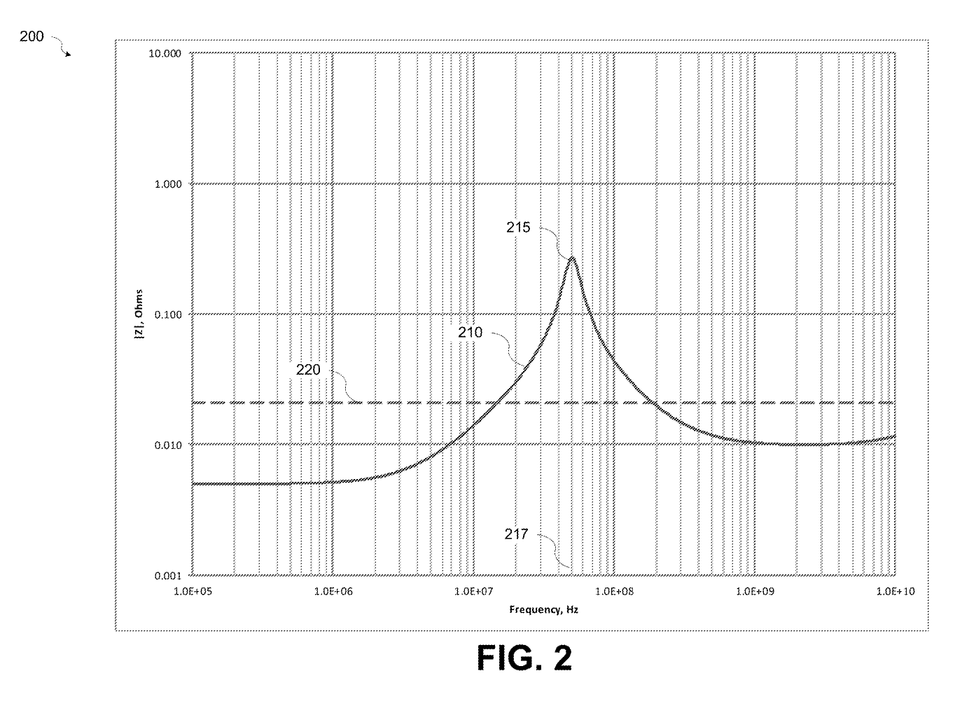

FIG. 2 is a graph 200 illustrating an impedance barrier between the PDN and an IC. Referring to FIGS. 1 and 2, for switching circuitry 110 switching, or having spectral content, at a frequency of approximately 50 MHz, the total impedance curve 210, i.e., the impedance barrier, reaches a peak 215 greater than 20 milliohms at the resonant frequency 217 (i.e., approximately 50 MHz). As further illustrated in FIG. 2, the total impedance 210 at the resonant frequency 217 exceeds the target impedance value 220 of approximately 20 mili-ohms for acceptable switching circuitry 110 operation. The impedance target may be set based on an acceptable amount of switching noise generated by the switching current. One of ordinary skill in the art will appreciate that the values presented in FIG. 2 are merely exemplary.

### Adaptive Feedback

The impedance of the semiconductor package inductance to switching currents in switching circuitry, e.g., CMOS circuits, may contribute to the cause of the impedance barrier. IC or semiconductor package capacitance may be made more effective by sensing the high-frequency components of the voltage supplied to the IC or semiconductor package and controlling voltage across a local capacitance, for example, a bypass capacitor, to reduce noise variations by controlling the voltage on the capacitance. An amplifier may make the IC or semiconductor package capacitance more effective based on gain of the amplifier. The amplifier gain may be less than, greater than, or equal to one.

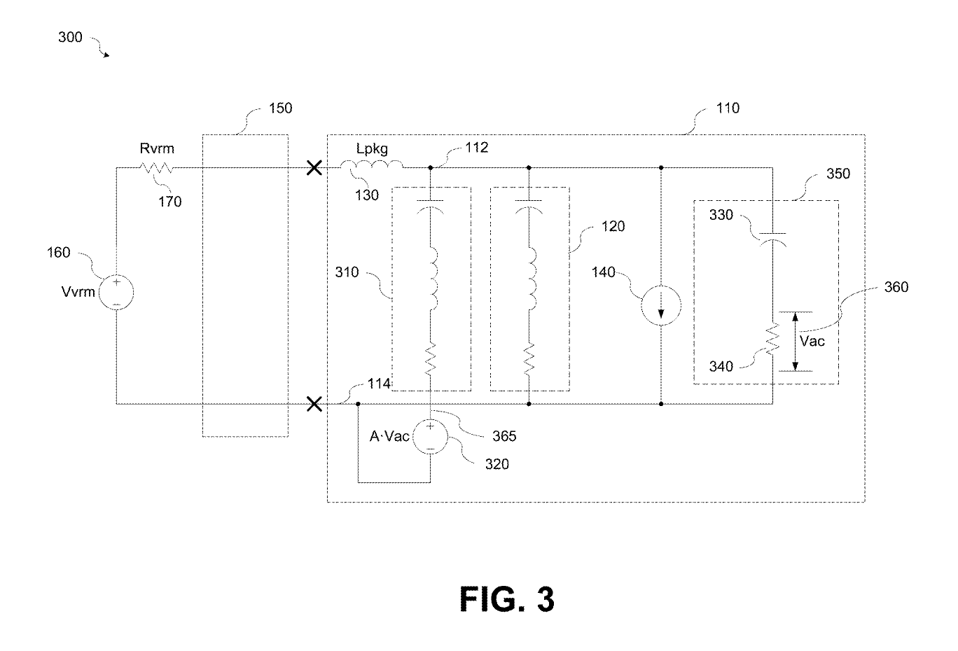

FIG. 3 is a schematic diagram conceptually illustrating an adaptive feedback circuit 300 according to various embodiments. Referring to FIG. 3, the adaptive feedback circuit 300 may include first capacitive element 310, a controlled source 320, and a second capacitive element 330, and a resistive element 340. The resistive element 340 may be for example, but not limited to, a resistor, and the first and second capacitive elements 310, 330 may be for example, but not limited to, capacitors. The controlled source 320 may be, for example, but not limited to, an amplifier.

The resistive element 340 and second capacitive element 330 may be electrically connected in series between the first power supply line 112 and the second power supply line 114 and may form a filter 350. The filter 350 may be configured as a high-pass filter. High-frequency components of the power supply voltage applied between the first power supply line 112 and the second power supply line 114 through the PDN 150 caused by variations in the switching current 140 due to changes in switching load may be filtered by the filter 350 and sensed across the first resistive element 340 as a high-frequency alternating current (AC) signal 360. The high-frequency alternating current (AC) signal 360 may be a voltage signal or a current signal and may be a control signal for the controlled source 320. One of ordinary skill in the art will appreciate that other methods of sensing the high-frequency components of the power supply voltage known to those of skill in the art may be used without departing from the scope of the inventive concept.

The high-frequency AC control signal 360 may control an output voltage signal of the controlled source 320. The first capacitive element 310 may have a first terminal electrically connected to the first power supply line 112 and a second terminal connected to the output of the controlled source 320. The output of the controlled source 320 may control the voltage across the first capacitive element 310 based on the high-frequency AC control signal 360. By controlling the voltage across the first capacitive element 310, current may be supplied to the first power supply line 112 by the first capacitive element 310 to compensate for the variations in power supply voltage between the first power supply line 112 and the second power supply line 114 caused by the variations in the switching current 140, thereby reducing the noise due to the impedance barrier.

For convenience, throughout the disclosure, the first capacitive element 310 will be referred to as a first capacitor 310, the second capacitive element 330 will be referred to as a second capacitor 330, the resistive element 340 will be referred to as a resistor 340, and the controlled source 320 will be referred to as an amplifier 320. One of ordinary skill in the art will appreciate that various elements and/or devices having the appropriate resistive, capacitive, and controlled source characteristics may be used without departing from the scope of the present inventive concept.

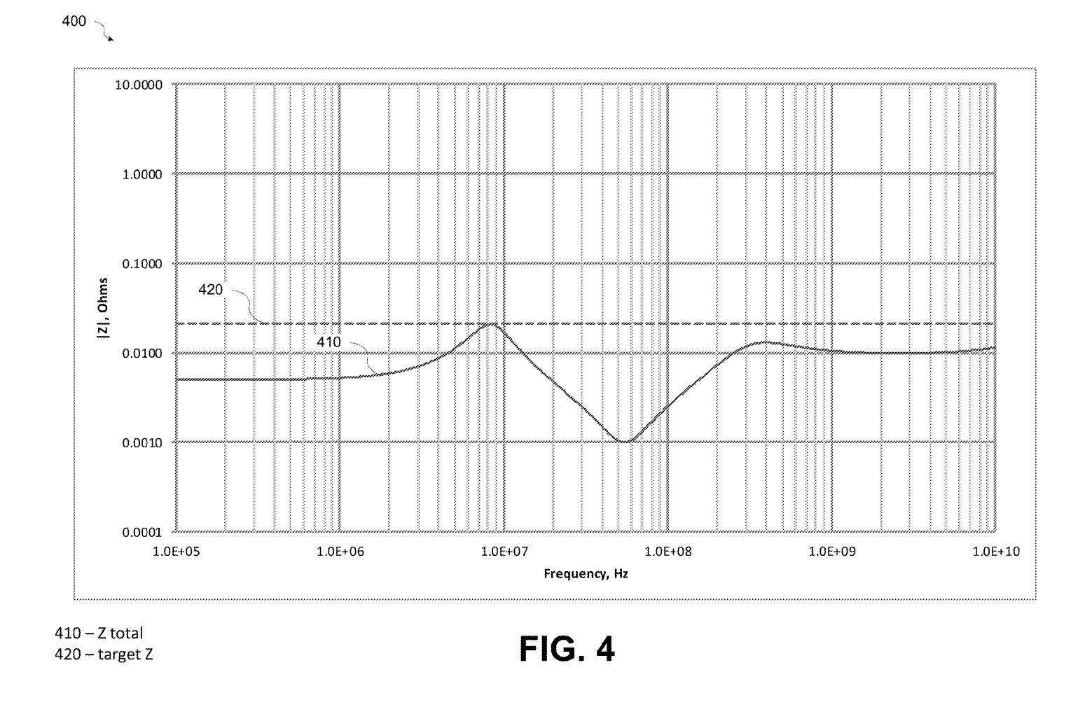

FIG. 4 is a graph 400 illustrating an impedance barrier between the PDN and a semiconductor die according to various embodiments. Referring to FIGS. 3 and 4, for switching circuitry 110 including the adaptive feedback circuit 300, the total impedance curve 410, i.e., the impedance barrier, does not exceed the target impedance value 420 of approximately 20 mili-ohms for acceptable switching circuitry 110 operation. The impedance target may be set based on an acceptable amount of switching noise generated by the switching current. One of ordinary skill in the art will appreciate that the values presented in FIG. 4 are merely exemplary.

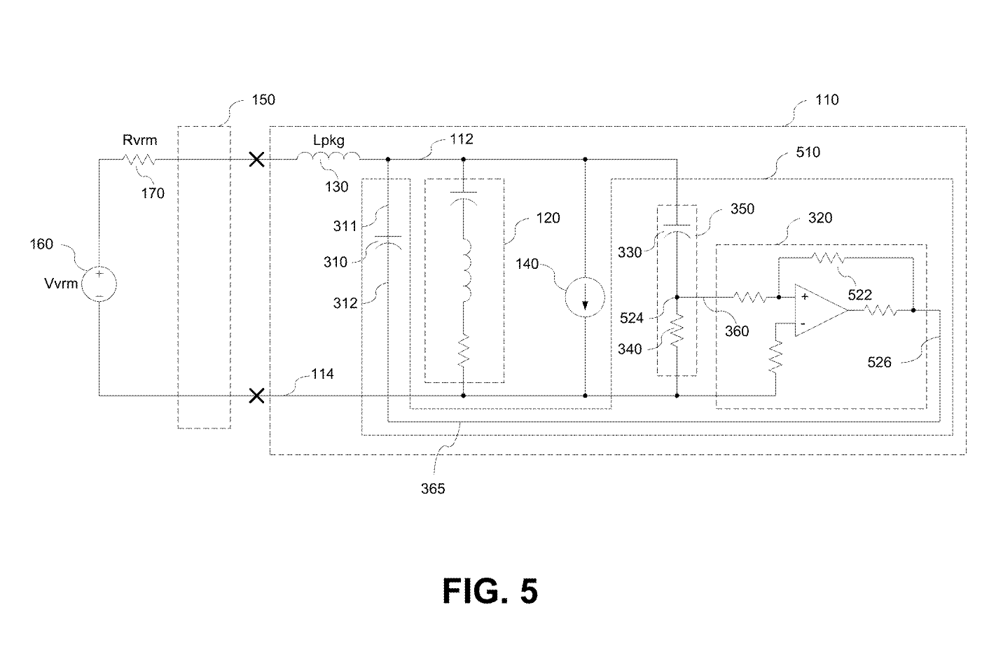

FIG. 5 is a schematic diagram illustrating an implementation of an adaptive feedback circuit 510 according to various embodiments. Referring to FIG. 5, the adaptive feedback circuit 510 may include a first capacitor 310, an amplifier 320, and a filter 350. A first terminal 311 of the first capacitor 310 may be electrically connected to the first power supply line 112. Alternatively, the first terminal 311 of the first capacitor 310 may be electrically connected to the second power supply line 114. The first capacitor 310 may be coupled proximately to a connection of the first power supply line 112 or the second power supply line 114 with a power supply external to the IC and/or may be configured as a bypass capacitor.

The amplifier 320 may be, for example, but not limited to, a voltage feedback amplifier. The amplifier 320 may include one or more feedback resistors 522. The one or more feedback resistors may be configured to adjust a gain of the amplifier 320. One of ordinary skill in the art will appreciate that other amplifier configurations known to those of skill in the art may be implemented without departing from the scope of the inventive concept.

The filter 350 may include one or more capacitors 330 electrically connected in series to one or more resistors 340. The filter 350 may be configured as a high-pass filter. The filter 350 may be configured to extract high-frequency components of the power supply voltage applied between the first power supply line 112 and the second power supply line 114 through the PDN 150. For example, the high-frequency components of the power supply voltage may be sensed as a high-frequency AC signal 360 developed across the one or more resistors 340. One of ordinary skill in the art will appreciate that other filter configurations known to those of skill in the art may be implemented without departing from the scope of the inventive concept.

An input of the amplifier 320 may be electrically connected to a common connection point 524 between the one or more capacitors 330 and the one or more first resistors 340 and may be configured to input the high-frequency AC signal 360 developed across the one or more resistors 340. The amplifier 320 may apply gain to the high-frequency AC signal 360 to generate an amplified high-frequency AC signal 365 at an output 526 of the amplifier 320. The amplified high-frequency AC signal 365 may be a voltage signal or a current signal. The gain of the amplifier 320 may be set, for example, based on a value of the feedback resistor 522.

The output of the amplifier 320 may be electrically connected to a second terminal 312 of the first capacitor 310 and may be configured to apply the amplified high-frequency AC signal 365 to the second terminal 312 of the first capacitor 310 to control a voltage across the first capacitor 310. The amplified high-frequency AC signal 365 generated by the amplifier may control the voltage applied between the first terminal 311 and the second terminal 312 of the first capacitor 310 proportional to the high-frequency signal output by the filter. By controlling the voltage across the first capacitive element 310, current may be supplied to the first power supply line 112 by the first capacitive element 310 to compensate for the variations in power supply voltage between the first power supply line 112 and the second power supply line 114 caused by the variations in the switching current 140, thereby reducing the noise due to the impedance barrier.

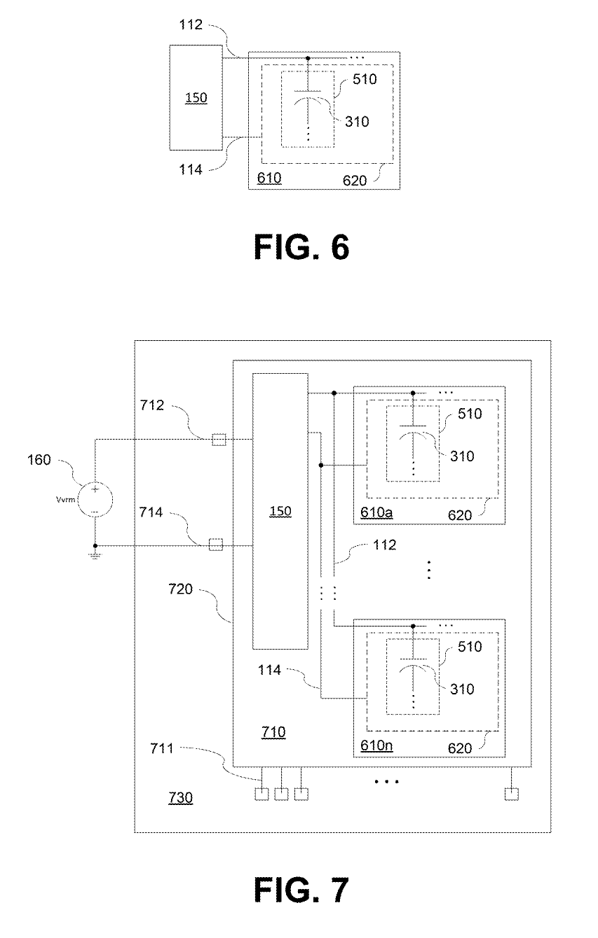

FIG. 6 is a block diagram illustrating an IC 610 having an adaptive feedback circuit according to various embodiments. Referring to FIGS. 5 and 6, an IC may include circuitry 620, for example, but not limited to, CMOS logic circuits and/or other switching circuits, and one or more adaptive feedback circuits 510. The one or more adaptive feedback circuits 510 are described with respect to FIG. 5; therefore, the description will not be repeated here.

The one or more adaptive feedback circuits 510 may control the voltage across the first capacitive element 310, current may be supplied to the first power supply line 112 by the first capacitive element 310 to compensate for the variations in power supply voltage between the first power supply line 112 and the second power supply line 114 caused by the variations in switching current, thereby reducing the noise due to the impedance barrier between the IC 610 and the PDN 150.

FIG. 7 is a block diagram illustrating an SoC having an adaptive feedback circuit according to various embodiments. Referring to FIGS. 5, 6, and 7, an SoC 710 may include one or more ICs 610 having, for example, but not limited to, CMOS logic circuits and/or other switching circuits, a PDN 150, and one or more adaptive feedback circuits 510. The one or more adaptive feedback circuits 510 are described with respect to FIG. 5 and the one or more ICs 610 are described with respect to FIG. 6; therefore, the descriptions will not be repeated here.

The SoC 710 may be mechanically enclosed in a package 720 mounted on a printed circuit board (PCB) 730. The package 720 may include one or more electrical leads 711 configured to connect the SoC to the printed circuit board 730. Two or more of the electrical leads 711 may be connected to a third power supply line 712 and a fourth power supply line 714 from the power supply 160. The PDN 150 may receive power from the power supply 160 and supply power to the one or more ICs 610 through the first power supply line 112 and the second power supply line 114. One or more of the ICs 610 may include an adaptive feedback circuit 510.

In some embodiments, one or more adaptive feedback circuits 510 may be provided to the SoC 710 external to the one or more ICs 610. The one or more adaptive feedback circuits 510 may control the voltage across the first capacitive element 310, current may be supplied to the first power supply line 112 by the first capacitive element 310 to compensate for the variations in power supply voltage between the first power supply line 112 and the second power supply line 114 caused by the variations in switching current, thereby reducing the noise due to the impedance barrier between the IC 610 and the PDN 150. The first capacitor 310 one or more adaptive feedback circuits 510 may be coupled proximately to a connection of the first power supply line 112 or the second power supply line 114 with a power supply external to the one or more ICs 610 and/or may be configured as a bypass capacitor.

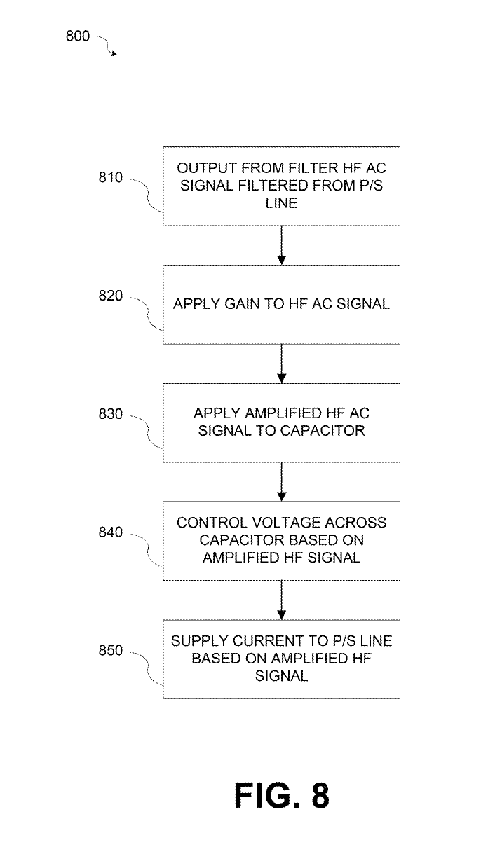

FIG. 8 is a flow chart illustrating a method 800 of reducing noise in a circuit according to various embodiments. Referring to FIG. 8, power received from a power supply (e.g., the power supply 160) through a PDN (e.g., the PDN 150) may be filtered to extract a high-frequency AC signal 360 from a first power supply line 112 and a second power supply line 114, and the high-frequency AC signal 360 may be output from the filter (e.g., the filter 350) (810). An amplifier (e.g., the amplifier 320) may apply gain to the high-frequency AC signal 360 to generate an amplified high-frequency AC signal 365 (820). The high-frequency AC signal 360 and the amplified high-frequency AC signal 365 may be voltage signals or current signals.

The amplified high-frequency AC signal 365 may be applied to a capacitor (e.g., the capacitor 310) having a terminal connected to one of a positive power supply line and a negative power supply line (830). The amplified high-frequency AC signal 365 may control the voltage across the capacitor proportional to the high-frequency AC signal 360 output by the filter (840). By controlling the voltage across the capacitor, current may be supplied to one of the positive and negative power supply lines by the capacitor based on the amplified high-frequency AC signal 360 (850). The supplied current may compensate for the variations in power supply voltage between the positive and negative power supply lines caused by the variations in switching current, thereby reducing the noise due to the impedance barrier.

Implementation of the inventive concept may vary according to application and technology using known circuit designs, for example amplifier and/or filter designs, and methods. In some embodiments, the adaptive feedback circuit may be included on a CMOS SoC die. In some embodiments, the control circuitry (e.g., the filter 350 and amplifier 320) may be on-die and the decoupling capacitance (e.g., the first capacitor 310) may be in-package to keep the die size to a minimum while keeping inductance low.

In some embodiments, a power supply/power management device, for example, but not limited to a power large scale integrated circuit (PLSI) and/or a power management integrated circuit (PMIC), may include one or more high efficiency switching regulators. In this case the adaptive feedback circuit may be integrated on-die, as a discrete external circuit, or some hybrid integrated-external circuit combination. In some embodiments, the adaptive feedback circuit may include circuits to limit in-rush currents when power is applied to the capacitor.

While certain embodiments have been described, these embodiments have been presented by way of example only, and are not intended to limit the scope of the protection. The methods and systems described herein may be embodied in a variety of other forms. Various omissions, substitutions, and/or changes in the form of the example methods and systems described herein may be made without departing from the spirit of the protection.

The accompanying claims and their equivalents are intended to cover such forms or modifications as would fall within the scope and spirit of the protection. For example, the example systems and methods disclosed herein can be applied to any electronic devices, including data storage devices such as hard disk drives, hybrid hard drives, solid state drives and the like, and/or any electronic devices having switching loads. In addition, other forms of storage, for example, but not limited to, DRAM or SRAM, battery backed-up volatile DRAM or SRAM devices, EPROM, EEPROM memory, etc., may additionally or alternatively be used. As another example, the various components illustrated in the figures may be implemented as software and/or firmware on a processor, ASIC/FPGA, or dedicated hardware. Also, the features and attributes of the specific example embodiments disclosed above may be combined in different ways to form additional embodiments, all of which fall within the scope of the present disclosure.

Although the present disclosure provides certain example embodiments and applications, other embodiments that are apparent to those of ordinary skill in the art, including embodiments which do not provide all of the features and advantages set forth herein, are also within the scope of this disclosure. Accordingly, the scope of the present disclosure is intended to be defined only by reference to the appended claims.

What is claimed is:

1. An adaptive feedback circuit, comprising:
a filter having a first terminal coupled to a first power supply line and a second terminal coupled to a second power supply line, the filter configured to output a high-frequency signal that is transmitted between the first and second power supply lines;
an amplifier configured to receive the high-frequency signal output from the filter and generate an amplified high-frequency signal at an output of the amplifier; and
a capacitor having a first terminal coupled to the first power supply line and a second terminal coupled to the output of the amplifier,
wherein the capacitor is configured to receive the amplified high-frequency signal, and the amplified high-frequency signal generated by the amplifier controls a voltage applied between the first terminal and the second terminal of the capacitor.

2. The adaptive feedback circuit of claim 1, wherein the capacitor is coupled proximately to a connection of the first power supply line or the second power supply line with an external power supply.

3. The adaptive feedback circuit of claim 1, wherein the amplified high-frequency signal generated by the amplifier controls the voltage applied between the first terminal and the second terminal of the capacitor proportional to the high-frequency signal output by the filter.

4. The adaptive feedback circuit of claim 1, wherein the first power supply line is a positive power supply line and the second power supply line is a negative power supply line.

5. The adaptive feedback circuit of claim 1, wherein the first power supply line is a negative power supply line and the second power supply line is a positive power supply line.

6. The adaptive feedback circuit of claim 1, wherein the filter is a resistive-capacitive high-pass filter.

7. An integrated circuit (IC), comprising:
an adaptive feedback circuit, the adaptive feedback circuit comprising:
a filter having a first terminal coupled to a first power supply line and a second terminal coupled to a second power supply line, the filter configured to output a high-frequency signal transmitted between the first and second power supply lines;
an amplifier configured to receive the high-frequency signal output from the filter and generate an amplified high-frequency signal at an output of the amplifier; and
a capacitor having a first terminal coupled to the first power supply line and a second terminal coupled to the output of the amplifier,
wherein the capacitor is configured to receive the amplified high-frequency signal, and the amplified high-frequency signal generated by the amplifier controls a voltage applied between the first terminal and the second terminal of the capacitor, and
wherein the capacitor is coupled proximately to a connection of the first power supply line or the second power supply line with a power supply external to the IC.

8. The IC of claim 7, wherein the amplified high-frequency signal generated by the amplifier controls the voltage applied between the first terminal and the second terminal of the capacitor proportional to the high-frequency signal output by the filter.

9. The IC of claim 7, wherein the first power supply line is a positive power supply line and the second power supply line is a negative power supply line.

10. The IC of claim 7, wherein the first power supply line is a negative power supply line and the second power supply line is a positive power supply line.

11. The IC of claim 7 of claim 7, the filter is a resistive-capacitive high-pass filter.

12. A System-on-Chip (SoC), comprising:
a plurality of integrated circuits (ICs) configured to perform operational functions of the SoC;
a power distribution network configured to supply power to at least one of the plurality of ICs; and
a package configured to mechanically enclose the plurality of ICs and the power distribution network, the package comprising one or more electrical leads configured to connect the SoC to a printed circuit board,
wherein the at least one of the plurality of integrated circuits comprises:
an adaptive feedback circuit, comprising:
a filter having a first terminal coupled to a first power supply line and a second terminal coupled to a second power supply line, the filter configured to output a high-frequency signal transmitted between the first and second power supply lines;
an amplifier configured to receive the high-frequency signal output from the filter and generate an amplified high-frequency signal at an output of the amplifier; and
a capacitor having a first terminal coupled to the first power supply line and a second terminal coupled to the output of the amplifier,
wherein the capacitor is configured to receive the amplified high-frequency signal, and the amplified high-frequency signal generated by the amplifier controls a voltage applied between the first terminal and the second terminal of the capacitor.

13. The SoC of claim 12, wherein the amplified high-frequency signal generated by the amplifier controls the voltage applied between the first terminal and the second terminal of the capacitor proportional to the high-frequency signal output by the filter.

14. The SoC of claim 12, wherein the first power supply line is a positive power supply line and the second power supply line is a negative power supply line.

15. The SoC of claim 12, wherein the first power supply line is a negative power supply line and the second power supply line is a positive power supply line.

16. The SoC of claim 12, the filter is a resistive-capacitive high-pass filter.

17. The SoC of claim 12, wherein the adaptive feedback circuit is disposed internal to the at least one of the plurality of ICs, and
wherein the capacitor is coupled proximately to a connection of the power distribution network with the at least one of the plurality of ICs.

18. The SoC of claim 12, wherein the adaptive feedback circuit is disposed external to the at least one of the plurality of ICs, and
wherein the capacitor is coupled proximately to a connection of the power distribution network with the at least one of the plurality of ICs.

19. A method of reducing noise in a circuit, the method comprising:
filtering a high-frequency signal transmitted between a first power supply line and a second power supply line and outputting the high-frequency signal;
amplifying the high-frequency signal to generate an amplified high-frequency signal; and
supplying current to one of the first and second power supply lines based on the amplified high-frequency signal.

20. The method of claim 19, wherein the current is supplied to one of the first and second power supply lines through a capacitor having a first terminal coupled to one of the first and second power supply lines.

21. The method of claim 20, further comprising controlling a voltage applied between the first terminal and a second terminal of the capacitor proportional the amplified high-frequency signal.
